(19) United States
(12) Patent Application Publication
(10) Pub. No.: US 2012/0275228 A1
(43) Pub. Date: Nov. 1, 2012

(54) INTERNAL WORDLINE CURRENT LEAKAGE SELF-DETECTION METHOD, DETECTION SYSTEM AND COMPUTER-READABLE STORAGE MEDIUM FOR NOR-TYPE FLASH MEMORY DEVICE

(75) Inventor: HSIAO-HUA LU, CHU-PEI CITY (TW)

(73) Assignee: EON SILICON SOLUTION INC., CHU-PEI CITY (TW)

(21) Appl. No.: 13/095,989

(22) Filed: Apr. 28, 2011

(51) Int. Cl. G11C 16/04

(52) U.S. Cl. 365/185.18

(57) ABSTRACT

A wordline internal current leakage self-detection method, system and a computer-readable storage medium thereof employ the originally existed high voltage supply unit and the voltage detector connected to the wordline in the flash memory device, in which the high voltage supply unit applies the test signal to the selected wordline, and the voltage detector detects the voltage signal of the wordline. By comparing the test signal with the voltage signal, the wordline will be indicated as current leakage when the voltage signal is lower than the test signal.

### FIELD OF TECHNOLOGY

The present invention relates to a self-detection method, system and computer-readable storage medium for NOR-type flash memory device, and particularly to a self-detection method, system and computer-readable storage medium for internal wordline current leakage of NOR-type flash memory device.

### BACKGROUND

Following the continuous development of semiconductor processing technology, the integrity of elements inside the semiconductor memory is increasingly enhanced. The extremely minor defects produced in the process will become the critical factors whether the semiconductor is failed. Recently, the fault detection for detecting the memory has become the critical standard procedure in the process.

Referring to FIG. 1, the figure shows a current leakage path when the wordline in NOR-type flash memory has occurred the current leakage. As shown in FIG. 1, the cell array 3 is provided with a plurality of cells, and each cell is provided a corresponding local wordline driver (not shown) inside a wordline driver set 1 to transmit a selection instruction for each cell in a row direction. Each cell is located at the intersection between a wordline WL and a bitline BL, and the neighbored two rows share a source line SL. The bitlines BL are driven by a row selector 5.

There are various reasons for occurrence of current leakage in NOR-type flash memory, such as wordline leakage P1 (between neighbored wordlines), junction leakage P2 (between gate and source/drain) or leakage from wordline driver itself P3. These current leakage situations will cause the flash memory being not able to be successfully programmed, erased, written or read. Conventionally, the memory test is conducted through erasing/programming/reading procedures by an external device to analyze and confirm the location of current leakage. However, during the actual testing, because the memory test conducted externally cannot clearly identify the location of current leakage, it is easily occurred with testing overhead and incorrect test results. And, in order to achieve more correct results, it is easily occurred with over-testing situations. Thus, the conventional memory testing methods have various inconveniences and disadvantages.

### SUMMARY

An object of the present invention is to provide a self-detection method, system and computer-readable storage medium for wordline current leakage in NOR-type flash memory device, which is able to directly conduct the self test inside the memory.

In order to achieve the above object and other objects, the internal wordline current leakage self-detection method according to the present invention includes the following steps: a high voltage supply unit as a boost circuit applying a high voltage test signal to a selected wordline; grounding the unselected wordlines, all the bitlines and all the source lines of a cell array; a voltage detector embedded inside the NOR-type flash memory device detecting a voltage signal of the wordline; and, comparing the high voltage test signal with the voltage signal, and determining the current leakage status of the wordline based on the voltage difference between the two signals.

In order to achieve the above object and other objects, the computer-readable storage medium storing with testing programs therein executes the above-mentioned self-detection method. In an embodiment, the computer-readable storage memory can further store the address of wordline with current leakage therein.

In order to achieve the above object and other objects, the internal wordline current leakage self-detection system according to the present invention comprises: a high voltage supply unit providing with a high voltage test signal; a voltage detector, which is electrically connected with all wordlines for detecting a voltage signal of the selected wordline; a control unit, which is electrically connected with the high voltage supply unit and the voltage detector to make the high voltage supply unit applying the high voltage test signal to the selected wordline, and to ground the unselected wordlines, all the bitlines and all the source lines of a cell array, and to receive the voltage signal of the wordline detected by the voltage detector to compare the high voltage test signal with the voltage signal, and determining the current leakage status of the wordline based on the voltage difference between the two signals.

In an embodiment according to the present invention, the internal wordline current leakage self-detection method is to determine all the wordlines for the current leakage status individually according to the address sequence.

In an embodiment according to the present invention, when the wordline is determined to be at current leakage status, the remaining redundant units can be used to directly replace the memory units below the wordline with current leakage.

Therefore, the direct detection for current leakage status from the internal circuit can greatly reduce the probability of fault determination, and precisely detect various possibilities of current leakage, such as current leakage between neighbored wordlines, current leakage between gate and source/drain, and even the current leakage of wordline driver itself.

### BRIEF DESCRIPTION OF THE DRAWINGS

FIG. 1 is a diagram of current leakage path for the wordline occurring with current leakage in NOR-type flash memory;

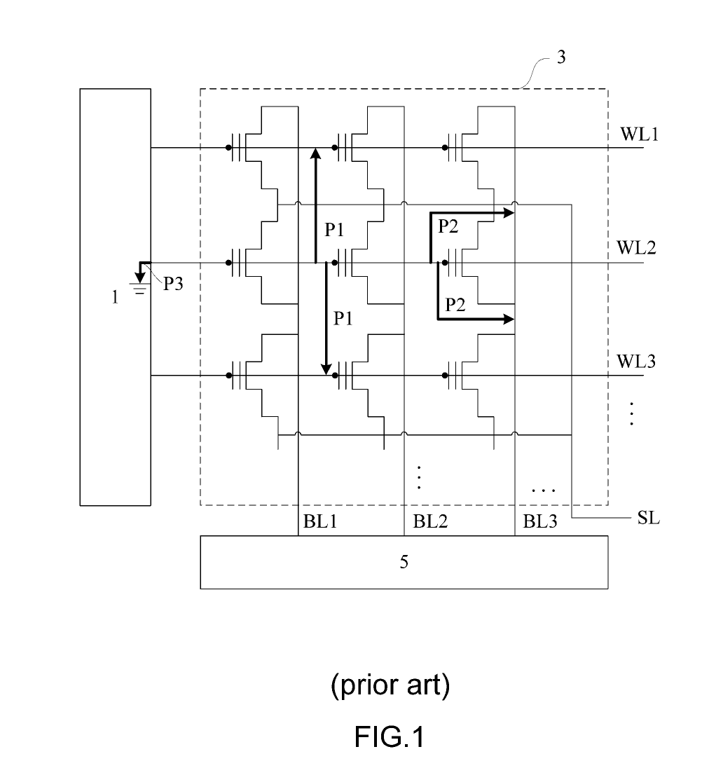

FIG. 2 is a configuration diagram of the self-detection system in an embodiment according to the present invention; and

FIG. 3 is a flow chart of the self-detection method in an embodiment according to the present invention.

### DETAILED DESCRIPTION

In order to fully appreciate the objects, features and effectiveness of the present invention, the present will be described in details with the following embodiments in connection with the attached figures.

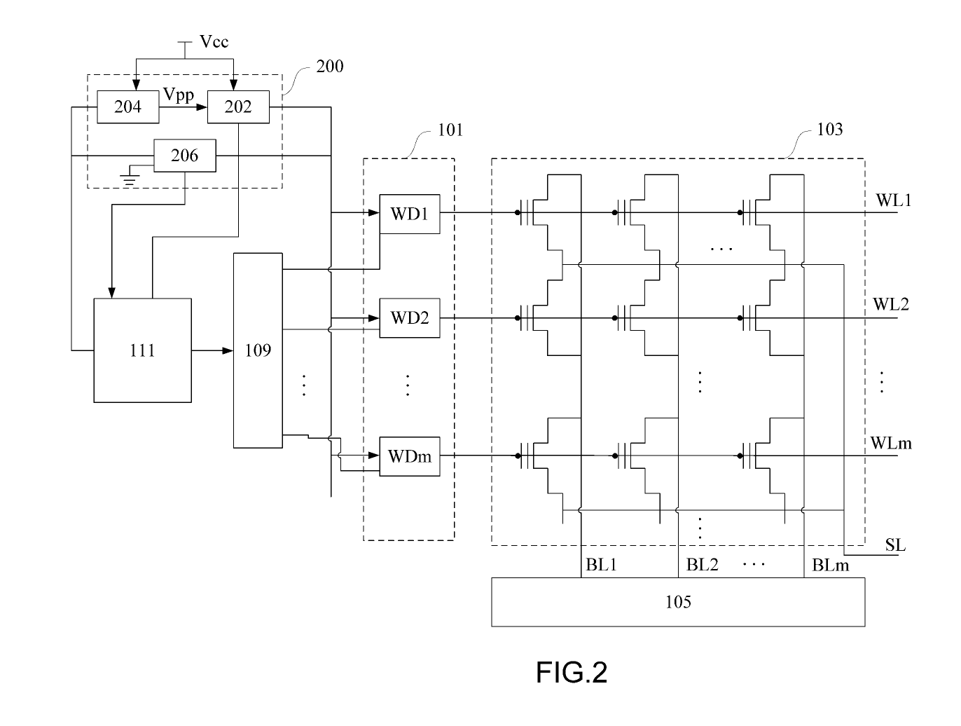

Referring to FIG. 2, the figure is a configuration diagram of the self-detection system in an embodiment according to the present invention. As for an ordinary NOR-type flash memory device, each memory unit in the cell array 103 is controlled by a wordline driver set 101 and a row selector 105. The wordline driver set 101 comprises a plurality of wordline drivers WD1˜WDm, and each wordline driver is connected with a wordline WL1˜WLm. The intersection of each wordline WL1˜WLm with the bitlines BL1-BLm is the location of one memory unit.

The high voltage supply/monitor device 200 selectively provides with the power supply voltage Vcc or boost voltage Vpp through the control of voltage switch circuit 202 and control unit 111 to the selected wordline driver WD1˜WDm. The high voltage supply unit 204 as a boost circuit is activated by the control unit 111, and employs the power supply voltage Vcc to generate the boost voltage Vpp after activation. The switch of the voltage switch circuit 202 is controlled by the control unit 111, and makes the output of the voltage switch circuit 202 as the power supply voltage Vcc under reading mode, and makes the output of the voltage switch circuit 202 as the boost voltage Vpp under programming or erasing mode, and further provides with the voltages required by the wordline drivers WD1˜WDm under various modes. In which, the control unit 111 usually comprises a counter and a status controller (not shown). The counter may be used for counting of wordline address, and the status controller may be used to control the operation of other units electrically connected thereto.

The voltage detector 206 is connected with each wordline driver WD1˜WDm, and used to monitor the voltage level on the wordline drivers WD1˜WDm. When the wordlines WL1˜WLm indicated by the column decoder 109 require a high voltage, the control unit will make the output of the voltage switch circuit 202 as a boost voltage Vpp, and the voltage detector 206 will detect/monitor the boost voltage Vpp. When the boost voltage Vpp did not reach the predetermined value, it will feedback a signal to the control unit 111, and the control unit 111 will make the high voltage supply unit 204 to increase the boost voltage to reach the predetermined value.

The column decoder 109 activate the specific wordline drivers WD1˜WDm according to the address instruction for the control unit 111, and further makes the voltage supplying to the selected wordlines WL1˜WLm.

The present invention employs such internally operating mechanism to proceed the internal current leakage self-detection method for wordlines WL1˜WLm.

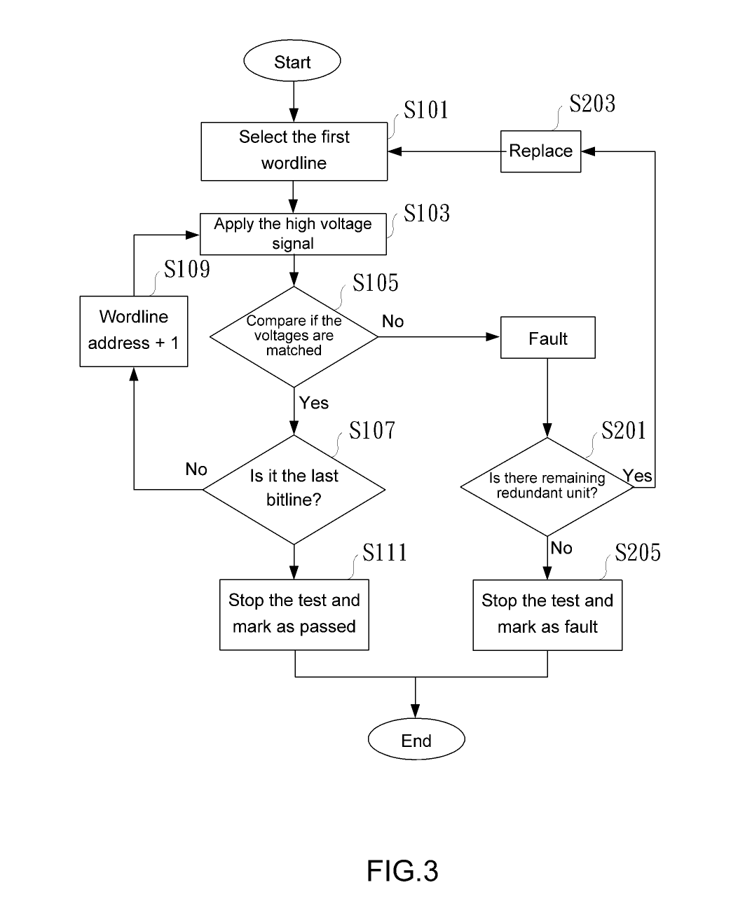

Referring to FIG. 3, the figure is a flow chart of the self-detection method in an embodiment according to the present invention. First, in the step S101, select the wordline with a specific address through the control unit 111 and the column decoder 109, which starts with the first bitline with the most front address in the cell array 103 in this embodiment. However, the selection method with other sequence can also be suitable for the present invention.

In Step S103, the high voltage supply unit 204 and the voltage switch circuit 202 apply a high voltage detection signal to the selected wordline. At this time, the control unit 111 simultaneously connects the other unselected wordlines, all the bitlines and all the source lines of the cell array to the ground.

In Step S105, the voltage detector 206 measures the voltage signal of the selected wordline, and transmits it to the control unit 111. The control unit 111 compares the high voltage test signal with the voltage signal. If the high voltage test signal is matched with the voltage signal, it indicates there is not current leakage for the selected wordline; if the high voltage test signal has a voltage difference with the voltage signal, and is not matched therewith, it indicates there is a current leakage for the selected wordline, and marks the bitline as fault. In other embodiments, it can also consider a tolerance and set the voltage difference within a certain range representing no current leakage.

In Step S107, the control unit 111 determines if there is any wordline not being tested. In this embodiment, it is determined if the wordline being tested currently is the last wordline in a sequence; if so, entering Step S111, and the control unit 111 will stop the testing step, and mark the cell array as passed; if not, entering Step S109, and the address counting of this cell array will be incremented with one, which returns to Step S103 to select the next wordline, and continue the testing step.

The above-mentioned testing method is a sequential test with automatic counting, but the other kind of sequence can also be suitable for the present invention.

The above-mentioned method employs the current leakage self-detection system according to the present invention to complete the internal wordline current leakage self-detection method. The test program for these methods can also be stored in a computer-readable storage medium, such as an external memory unit or a memory block in the control unit 111.

Moreover, the detected wordline address with current leakage status as described above can also be stored in a computer-readable storage medium, such as an external memory unit or a memory block in the control unit 111.

Furthermore, a preferred embodiment according to the present invention further employs the redundant units to replace the memory units below the fault wordlines. In such an embodiment, the cell array 103 comprises a lot of redundant units for replacing the memory units below the fault wordlines. Thus, after Step S105 determined the selected wordline having current leakage (being fault), Step S201 is executed to determine if there is still remaining redundant unit; if so, entering Step S203 to replace the memory units below fault wordlines with the remaining redundant units, and then the remaining amount of redundant units will be decremented with one; if not, entering Step S205, and the control unit 111 stops the testing step, and marks the cell array as being fault.

The measurement result for selected wordlines will be outputted by the control unit 111 to the outside with the information for passing the test or not; and, when the wordline is determined with current leakage (being fault), it will output the address information for the wordline based on the calculation of the counter.

In a summary, the present invention does not need external testing equipment and employs the programmed testing program to conduct the wordline current leakage self-detection directly inside the NOR-type flash memory device, and further precisely detect various possibilities of current leakage, such as current leakage between neighbored wordlines, current leakage between gate and source/drain, and even the current leakage of wordline driver itself.

The present invention has been disclosed in the above context with preferred embodiments. However, the skilled in the art should appreciate that these embodiments are only used to describe the present invention, and should not be comprehended as limiting the scope of the present invention. It should be noted that all the modifications and variations equivalent to these embodiments should be within the scope of the present invention. Thus, the protection scope for the present invention should be only defined by the claims.

What is claimed is:

1. An internal wordline current leakage self-detection method for NOR-type flash memory device, the method including the following steps:
a high voltage supply unit as a boost circuit applying a high voltage test signal to a selected wordline;
grounding the unselected wordlines, all the bitlines, and all the source lines of a cell array;
a voltage detector embedded in the NOR-type flash memory device detecting a voltage signal of the wordline; and,
comparing the high voltage test signal with the voltage signal to determine the current leakage status of the wordline based on the voltage difference between the two signals.

2. The method according to claim 1, wherein the internal wordline current leakage self-detection method is to determine the current leakage status for all the wordlines individually according to the address sequence.

3. The method according to claim 2, wherein, after determining the wordline with current leakage status, further includes the following steps:
reading out the address for the wordline and marking as being fault; and,
employing the remaining redundant units to replace the memory units below the wordline.

4. The method according to claim 3, wherein, after replacing the memory units below the wordline with the remaining redundant units, further includes the following steps:
re-detecting the initially selected wordlines according to the address sequence.

5. A computer-readable storage medium, which stores the test program therein for the computer to load the test program and execute to complete the method according to claim 1.

6. The computer-readable storage medium according to claim 5, which stores the wordline address with current leakage therein.

7. An internal wordline current leakage self-detection system for NOR-type flash memory device, which comprises:
a high voltage supply unit, which provides a high voltage test signal;
a voltage detector, which is electrically connected with all wordlines for detecting the voltage signal of the selected wordline;
a control unit, which is electrically connected with the high voltage supply unit and the voltage detector so as to make the high voltage supply unit applying the high voltage test signal to the selected wordlines, and to ground the unselected wordlines, all the bitlines, and all the source lines of a cell array, and receive the voltage signal of the wordline measured by the voltage detector to compare the high voltage test signal with the voltage signal, and determine the current leakage status for the wordline based on the voltage difference between the two signals.

8. The system according to claim 7, which further comprises:
at least one redundant unit, which is used when the wordline has the current leakage status, and the control unit employs the at least one redundant unit to replace the memory unit below the wordline.
